(19) United States
(12) Patent Application Publication
(10) Pub. No.: US 2012/0111726 A1
(43) Pub. Date: May 10, 2012

(54) Sensor Element Having Through-Hole Plating

(76) Inventors: Dulce Maria Couto Petri, Gerlingen (DE); Oliver Dotterweich, Oberhaid (DE); Antje Taeuber, Hirschaid (DE); Jens Schneider, Leonberg (DE); Thomas Leuschner, Bischberg (DE); Christoph Renger, Bamberg (DE); Michael Sauerhammer, Bamberg (DE); Andreas Rottmann, Settfeld (DE)

(21) Appl. No.: 13/383,481

(22) PCT Filed: Jul. 14, 2010
(86) PCT No.: PCT/EP10/60121

§ 371 Date: Jan. 11, 2012

(30) Foreign Application Priority Data
Aug. 3, 2009 (DE) 102009028194.0

(51) Int. Cl. G01N 27/406; G01N 27/407; G01N 27/28; G01R 3/00

(52) U.S. Cl. 204/424; 29/592.1

(57) ABSTRACT

A sensor element and a method of producing a sensor element is described. The sensor element being especially for identifying a physical property of a gas, especially for identifying the concentration of a gas component or the temperature of an exhaust gas of an internal combustion engine. The sensor element has a first solid electrolyte layer, the first solid electrolyte layer having a plated- through hole. The sensor element also has a conducting element which produces an electrically conducting connection from the upper side of the first solid electrolyte layer to the lower side of the first solid electrolyte layer through the plated-through hole. The first solid electrolyte layer in the plated-through hole is electrically insulated from the conducting element by an insulating element. The wall of the plated-through hole has a bevel.

### FIELD OF THE INVENTION

The present invention relates to sensor elements which are based on the electrolytic properties of specific solids, thus on the ability of these solids to conduct specific ions. Such sensor elements are used particularly in motor vehicle, especially as lambda probes. However, the present invention may also be applied to other types of sensor elements, which include solid electrolytes of the type described, for instance, to sensors for detecting other gaseous components of exhaust gases and to particle sensors. The present invention relates to a sensor element as well as a method for producing a sensor element, particularly a sensor element according to the present invention.

### BACKGROUND INFORMATION

One problem in the production of sensor elements that have at least one solid electrolyte layer is that electrical through-hole platings have to be produced through the solid electrolyte layer which should not be in conductive contact with the solid electrolyte layer. The plated-through holes are therefore electrically insulated, as a rule, from the solid electrolytes by an insulating layer.

The through-hole plating, described in German Patent No. DE 100 14 995 C1, has conductive and insulating layers which are situated in a plated-through hole in a solid electrolyte layer of a ceramic measuring sensor. In this instance, the plated-through hole has the shape of a straight circular cylinder, whose axis is situated perpendicular to the surface of the solid electrolyte layer. The wall of the plated-through hole impinges upon the surface of the electrolyte layer along a rectangular edge.

The disadvantage in the conventional through-hole plating is that, in the production process, it is difficult to ensure that the thickness of the insulating layer in the plated-through hole lies between a minimum thickness and a greatest admissible thickness. In particular, it is difficult to ensure that, in the area of the edges of the plated-through hole, the minimum thickness is not undershot. That would impair the insulating effect of the insulating layer. Furthermore, it is particularly difficult to ensure that, in the area of the wall of the plated-through hole, especially in the area under the edges of the plated-through hole, a maximum admissible thickness of the insulating layer is not exceeded. Such an exceeding has the consequence, in the production process, that an excessive quantity of solvent from the substance used to produce the insulating layer is able to get into the substance used for producing the solid electrolyte layer, whereby this substance is impaired, and this can lead to cracks appearing in the finished solid electrolyte layer.

By contrast, sensor elements according to the present invention may have the advantage that they are easy to produce, in particular because it is easy to ensure that the insulation in the area of the plated-through hole has a specified layer thickness.

Because the wall of the plated-through hole has a bevel, the accessibility of the wall of the plated-through hole improves for the application of substances for producing an insulating layer. Furthermore, because of the bevel provided according to the present invention, it is avoided that the wall of the plated-through hole and the outer surface of the solid electrolyte layer come into a sharp-edged impact with each other along an edge. Because of this, on the one hand it can be avoided in the production process that, in the area of the edge, a thin, or even interrupted insulation occurs, and on the other hand, the creation of too thick an insulating layer on the inside of the through-hole plating may also be avoided.

As the minimum thickness, one should regard a thickness of the insulation between 5 μm and 20 μm, for example, a thickness of 10 μm. As the greatest admissible thickness, one should regard a thickness of the insulation in the range between 15 μm and 35 μm, for instance, a thickness of 20 μm. It is especially favorable, particularly in the interplay with the shape of the plated-through hole, to provide the insulation with a layer thickness which, at least generally, lies in the entire plated-through hole between the minimum thickness and the greatest admissible thickness.

By a bevel, one generally understands an area situated between a first and a second area, whose inclination is greater than the inclination of the first area and less than the inclination of the second area.

Within the scope of this application, one should understand the bevel to be a wall of a plated-through hole of a solid electrolyte layer, in particular a part of the wall of the plated-through hole, which is situated between a large area of the solid electrolyte layer and a further part of the wall of the plated-through hole, the inclination of the wall in the further part of the wall being at least generally constant in the radial direction, and being particularly at least generally perpendicular to the inclination of the large area of the solid electrolyte layer; in the part of the wall of the plated-through hole, the inclination of the wall in the radial direction lying between the inclination of the wall between the inclination of the wall in the radial direction in the further part of the wall of the plated-through hole and the inclination of the large area of the solid electrolyte layer.

Such a part of the wall of a plated-through hole of a solid electrolyte layer should be understood to be a bevel, particularly if it is more extensive than an area which is of necessity created usually, and as a condition of production, during the production of a plated-through hole in a solid electrolyte layer. Such regions reach, for example, down to a depth of less than 1 μm, especially less than 3 μm, in particular less than 9 μm of the plated-through hole.

By inclination of the wall of a plated-through hole in the radial direction, the inclination of the wall of a plated-through hole in the direction which is locally oriented perpendicular to the encircling edge of the plated-through hole. If there exists a cylindrical axial symmetry of the plated-through hole, this is the direction which points from the axis of the plated-through hole to the wall of the plated-through hole.

Large areas of a solid electrolyte layer are understood to be their upper side and their lower side.

If the bevel reaches to a depth of not less than 25 μm, particularly not less than 75 μm, into the plated-through hole and/or if the bevel reaches to a depth of not less than 5% of the thickness of the first solid electrolyte layer, particularly not less than 15% of the thickness of the first solid electrolyte layer, into the plated-through hole, the named advantageous effects of the bevel are particularly notable, for instance, the accessibility of the wall of the plated-through hole for the application of substances for producing an insulating layer is improved particularly clearly.

If the bevel has at least one straight area, which is straight in the radial direction, the straight area of the bevel extending particularly over the entire bevel, this brings about the advantage that such a bevel may be produced especially simply, using usual tools. If, in addition, the straight area of the bevel forms with the upper side of the first solid electrolyte layer and/or the lower side of the first solid electrolyte layer an angle of not less than 15° and not more than 75°, especially of not less than 30° and not more than 60°, the sharp edge properties in the area of the edge of the plated-through hole are avoided especially effectively.

Sharp edge properties in the area of the edge of the plated-through hole are also avoided especially effectively if the bevel has at least one curved area that is rounded off in the radial direction, particularly if the corresponding radius of curvature amounts to 10 μm to 200 μm, particularly 25 μm to 115 μm, especially if the curved area of the bevel extends over the whole bevel and/or especially if the plated-through hole has a concave shape in the area of the curved bevel.

One possible optimization of the bevel with respect to its advantageous effects becomes possible if the bevel has two areas different from each other, a first partial bevel and a second partial bevel.

What is further provided is that the first partial bevel is situated within the second partial bevel in a top view onto the solid electrolyte foil.

Alternatively or in addition, it is provided that the second partial bevel be situated between a large area of the solid electrolyte layer and the first partial bevel, in the second partial bevel, an inclination of the wall in the radial direction lying between an inclination of the wall in the radial direction in the first partial bevel and the inclination of the large surface of the solid electrolyte layer. The second partial bevel then represents, so to speak, a bevel of the bevel of the wall of the plated-through hole. In this case, very extensive advantages come about which concern the simple producibility of the sensor element and the reliability of the insulation in the area of the plated-through hole, and finally, along with that, the service life of the sensor element.

If the second partial bevel reaches to a depth of not less than 10 μm, particularly of not less than 30 μm, into the plated-through hole, and/or reaches to a depth of not less than 2.5% of the thickness of the first solid electrolyte layer, particularly of not less than 7.5% of the thickness of the first solid electrolyte layer, into the plated-through hole, the accessibility of the wall of the plated-through hole for applying substances for producing an insulating layer is particularly clearly improved.

If the second partial bevel reaches to a depth of not more than 100 μm, particularly of not more than 50 μm into the plated-through hole, and/or to a depth of not more than 20% of the thickness of the first solid electrolyte layer, particularly of not more than 10% of the thickness of the first solid electrolyte layer into the plated-through hole, it is particularly easy to produce it.

One example embodiment, in which, during the production of the sensor element, a complete wetting of the wall with insulating material is especially ensured, provides that the first partial bevel and the second partial bevel are each straight at least in places, in the radial direction, and will abut on each other in the radial direction at a partial bevel angle, particularly at a partial bevel angle of not less than 10° and of not more than 55°, especially at a partial bevel angle of not less than 25° and not more than 45°.

One additional example embodiment, in which, during the production of the sensor element, the complete wetting of the wall with insulating material is particularly ensured, provides that the second partial bevel includes, with the upper side of the solid electrolyte layer or the lower side of the solid electrolyte layer, an angle of not less than 3° and of not more than 25°, especially of not less than 6° and of not more than 16°.

Testing on the part of the Applicant has shown that the service life of the sensor elements is particularly long if the second partial bevel is straight in the radial direction at least in places, and the first partial bevel is rounded off at least in places in the radial direction, particularly having a radius of curvature of 10 μm to 200 μm, particularly having a radius of curvature of 25 μm to 115 μm, in particular, the second partial bevel and the first partial bevel in the radial direction impact each other at a partial bevel angle of less than 5°, particularly less than 1°, especially in a planar manner, and especially if the second partial bevel is at an angle to the upper side of the solid electrolyte layer or the upper side of the solid electrolyte layer, the lower side of the solid electrolyte layer includes an angle of not less than 3° and not more than 25°, especially of not less than 6° and not more than 16°.

Particularly advantageous for introducing the plated-through hole into the solid electrolyte foil is a mechanical drill, for example, or a stamping tool or even a laser beam are used, whose shape corresponds to the shape of the bore that is to be produced, or which has a subrange which has at least the shape of a part of the bore to be produced. Thus, the tool may have a cylindrical shape in a distal region which in proximal direction adjoins a region that is formed corresponding to the bevel of the plated-through hole. It is also possible to use a tool whose shape corresponds to the shape of the bevel of the plated-through hole, or which has a subregion which corresponds to the shape of the bevel or the shape of a part of the bevel.

If the tool is a laser beam, the shape of the laser beam should be understood to be within the meaning of DIN EN ISO 11145. When using a laser beam, the advantage comes about that undercuts may also be produced. Thus, for example, using only one-sided (laser) drilling, a plated-through hole is able to be introduced which has a bevel each at its upper side and at its lower side.

It is especially preferred if the insertion of an insulating paste and/or an insulating suspension into the plated-through hole takes place by suction on two sides, in each case the insulating paste and/or the insulating suspension being applied to a large area of the solid electrolyte foil, and subsequently being sucked or pressed through the plated-through hole using a pressure difference between the upper and the lower side of the solid electrolyte foil. Between the individual suction processes, in each case drying of the insulating paste and/or the insulating suspension is advantageously able to take place. It is provided that the solid electrolyte foil be turned over after the suction from the first side and before the suction from the second side.

In order to implement a through-hole plating that is resistant to ageing, it is of advantage that the conducting element and the insulating element are closely connected to each other which, in particular, is ensured by co-sintering. For the latter, a sintering temperature of 1350° C. to 1450° C. may be used.

### BRIEF DESCRIPTION OF THE DRAWINGS

FIG. 1 shows a schematic representation of a sensor element.

FIGS. 2a-2e show various example embodiments of the present invention.

FIG. 3 shows schematically the production of a sensor element.

FIGS. 4, 5a & 5b show the production of the through-hole plating of a sensor element.

### DETAILED DESCRIPTION OF EXAMPLE EMBODIMENTS

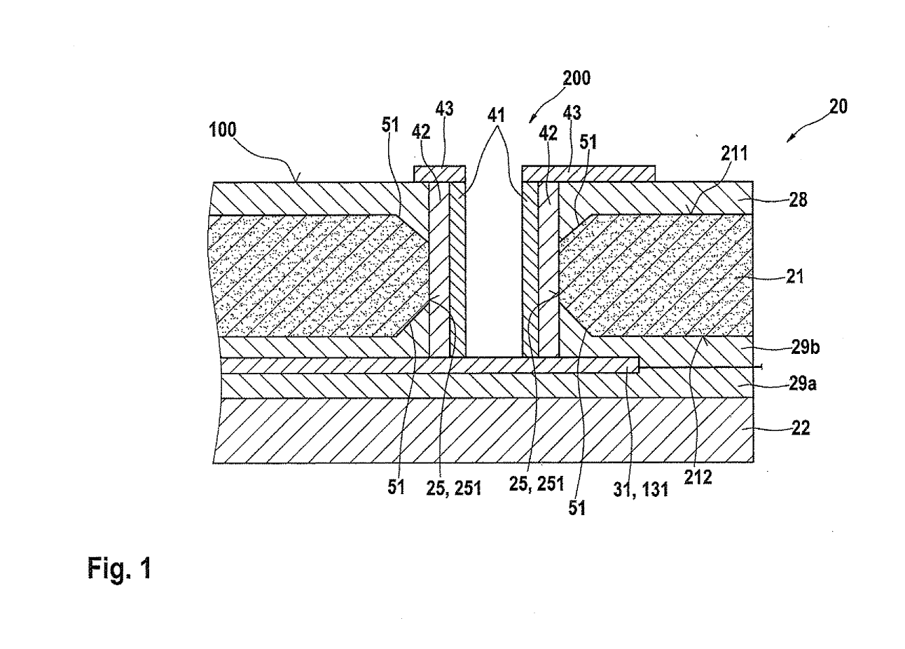

FIG. 1 shows, as an exemplary embodiment of the present invention, an end section on the connecting side of a sensor element 20, which is situated in the housing of a gas sensor (not shown), and is used, for example, to determine the oxygen concentration in the exhaust gas of an internal combustion engine (not shown) or the temperature of the exhaust gas.

Sensor element 20 is built up from ceramic layers 21, 22, 28, 29a, 20b, of which two are developed as a first and a second solid electrolyte foil 21, 22 and contain yttrium oxide-stabilized zirconium oxide (YSZ), two are developed as inner electrically insulating layers 29a, 29b and contain aluminum oxide and one is developed as an outer electrically insulating layer 28 and also contains aluminum oxide.

Below and above the inner electrically insulating layers 29a, 29b there are located the first and the second solid electrolyte foil 21, 22. Above first solid electrolyte foil 21 outer electrically insulating layer 28 is situated. Of course, sensor element 20 may have additional layers to implement functionalities of sensor element 20.

Between inner electrically insulating layers 29a, 29b there is a functional element 31, which is made up in this example of an electrical resistance heater and a supply line 131 to the electrical resistance heater. The electrical resistance heater, together with an outer circuit element (not shown), effects the heating of sensor element 20, for instance, to temperatures up to more than 650° C. Supply line 131 to the electrical resistance heater extends to the end section, on the connecting side, of sensor element 20, while the electrical resistance heater is situated in the opposite end section on the measuring side of sensor element 20, that is not shown in FIG. 1. Of course, functional element 31 may also have a different function, in connection with ceramic sensor elements.

In the vicinity of the end section on the connecting side, sensor element 20 has an electrical through-hole plating 200, which makes possible an electrical contacting of functional element 31 that is located on the inside of sensor element 20, via the outer surface 100 of sensor element 20. Accordingly, through-hole plating 200 extends, starting from functional element 31, through inner electrically insulating layer 29b, through first solid electrolyte foil 21 and through outer electrically insulating layer 28 right up to outer surface 100 of sensor element 20. For the purpose of through-hole plating 200, first solid electrolyte layer 21 has a plated-through hole 25. On the inside of through-hole plating 200 a layer-shaped insulating element 42 is situated which, starting from outer electrically insulating layer 28, extends via wall 251 of plated-through hole 25 to inner electrically insulating layers 29b, so that, because of insulating element 42 that is developed to be layer-shaped, and outer insulating layer 28, 29b, solid electrolyte layer 21 is completely surrounded by electrically insulating material, which contains aluminum oxide, for example, in the vicinity of through-hole plating 200, and within through-hole plating 200 a region is created which is electrically insulated from first solid electrolyte layer 21 even at high temperatures, for instance, temperatures of more than 400°. In this electrically insulated region, on layer-shaped insulating element 42, a conducting element 41, that is also layer-shaped, is situated which extends, starting from functional element 31, through through-hole plating 200, up to a contact surface 43 that is situated on outer surface 100 of sensor element 20, so that altogether an electrical contacting of functional element 31, that is located on the inside of sensor element 20 is created over outer surface 100 of sensor element 20, which is electrically insulated from first solid electrolyte layer 21.

Wall 251 of plated-through hole 25 has a bevel 51 each at its upper edge and its lower edge, which in each case represents a slantwise connection between one of the large areas of first solid electrolyte layer 21 and a part of wall 251 of plated-through hole 25 that is perpendicular to the large surfaces of first solid electrolyte layer 21. Electrically insulating material is located in the imaginary, encircling regions, cut out of first solid electrolyte layer 21 by bevels 51. As may be seen in FIG. 1, this material may be understood to be appertaining to electrically insulating layers 28, 29b, or appertaining to insulating element 42.

In this example, plated-through hole 25 has a diameter at its narrowest part that is in the range of 0.3 mm to 2 mm. Layer-shaped insulating element 42 and layer-shaped conducting element 41 have, on the inside of through-hole plating 200, layer thicknesses in the range of 5 to 100 μm. It is particularly preferred if the layer thickness of insulating element 42 is designed very homogeneously, so that it is always, or at least almost everywhere between a minimum thickness and a greatest admissible thickness, for instance, between 7 μm and 26 μm.

Bevels 51 shown in FIG. 1 should be understood to be a part of wall 251 of plated-through hole 25, which is situated between a large area of first solid electrolyte layer 21 and an additional part of the wall of plated-through hole 25, the inclination of the wall in the additional part of wall 251 of plated-through hole 25 in the radial direction being at least extensively constant, and in particular at least extensively perpendicular to the inclination of the large area of first solid electrolyte layer 21; in the part of wall 251 of plated-through hole 25, the inclination of wall 251, in the radial direction, lying between the inclination of wall 251 in the radial direction in the additional part of wall 251 of plated-through hole 25 and the inclination of the large area of first solid electrolyte layer 21.

In this example, insulating element 42 contains a proportion of 55 wt-% α-Al₂O₃ and a proportion of 45 wt-% of a highly insulating glass phase, for example, a celsian glass or a Ba—Si—La glass. Other proportions and other components are also possible.

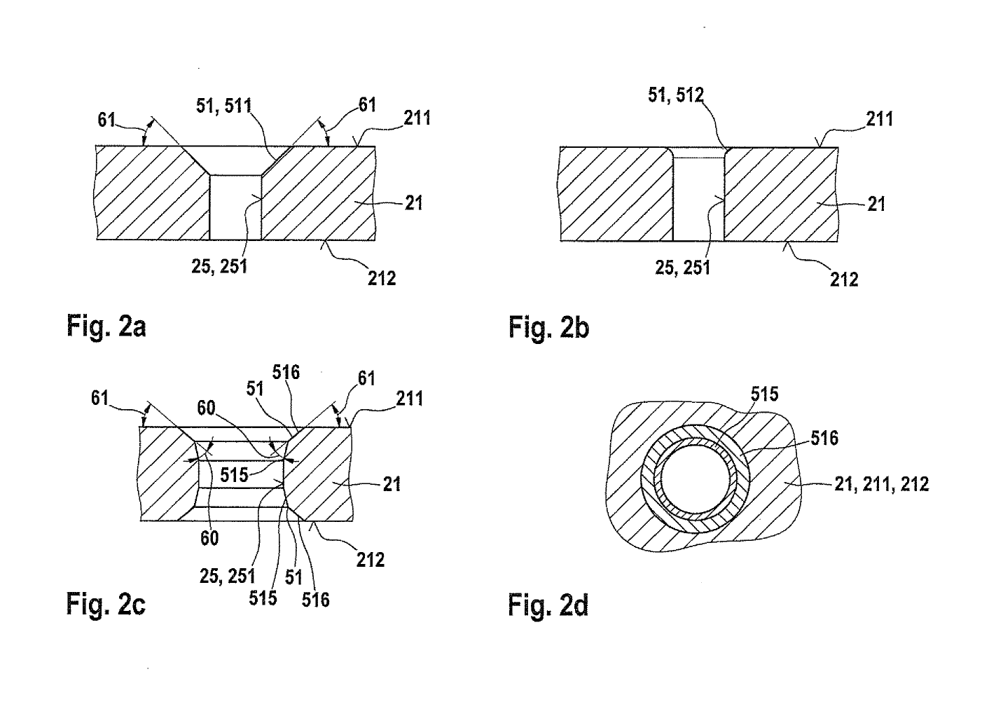

Specific example embodiments of the exemplary embodiment are shown in FIGS. 2a through 2e, and relate to refinements of the shape of bevel 51 of wall 251 of plated-through hole 25 in first solid electrolyte layer 21. In this context, in FIGS. 2a through 2e, for improved clarity, in each case only first solid electrolyte layer 21, plated-through hole 25 and one or more bevels 51 are shown, however, these specific example embodiments too are to be understood to be within the meaning of a sensor element shown in FIG. 1 in exemplary form. Of course, not all the specific embodiments of the present invention are restricted to ceramic sensor elements designed to be planar, but are transferable directly to other, for instance cylindrical geometries of a layer buildup.

Bevel 51 shown in FIG. 2a has a straight region 511, which is straight in the radial direction, and extends over the entire encircling bevel 51. Bevel 51 extends to a depth of 100 μm of first electrolyte layer 21 at a thickness of first electrolyte layer 21 of 400 μm. With reference to the large areas of first solid electrolyte layer 21, bevel 51 has an inclination of 45°, that is, the straight region 511 of bevel 51 includes an angle 61 of 45° with the large areas of first solid electrolyte layer 21.

Bevel 51 shown in FIG. 2b has a curved region 512, which is rounded off in the radial direction. In the radial direction, the curved region has a radius of curvature of 80 μm. Bevel 51 extends to a depth of 80 μm of first electrolyte layer 21 at a thickness of first electrolyte layer 21 of 400 μm.

Bevels 51 shown in FIGS. 2c and 2d are made up in each case of a first partial bevel 515 and a second partial bevel 516. In a top view onto solid electrolyte foil (FIG. 2d), first partial bevel 515 is situated within second partial bevel 516. The two bevels 515 and 516 abut on each other in the radial direction, at a partial bevel angle 60 of 37.5°. Second bevel 516 is inclined, with respect to the large area of solid electrolyte layer, at 22.5°.

Second partial bevel 516 is situated between a large area of solid electrolyte layer 21 and first partial bevel 515, and the inclination of wall 251, in the radial direction, in second partial bevel 516, is between the inclination of wall 251, in the radial direction, in first partial bevel 515 and the inclination of the large area of solid electrolyte layer 21.

Bevels 51 shown in FIG. 2e are each made up of a first partial bevel 515 and a second partial bevel 516. In a top view onto solid electrolyte foil 21, first partial bevel 515 is situated within second partial bevel 516 (as in FIG. 2d). The two partial bevels 515 and 516 go over into each other in a planar manner, without an edge. Second partial bevel 516 is a straight line in the radial direction, and is inclined with respect to the large area at 9.3°. Second partial bevel 516 extends to a depth of 38 μm into plated-through hole 25, which is about 10% of the thickness of first solid electrolyte layer 21. First partial bevel 515 is curved in the radial direction, the curvature having a radius of 55 μm.

Additional combinations of the features of demonstrated bevels 51 are also possible.

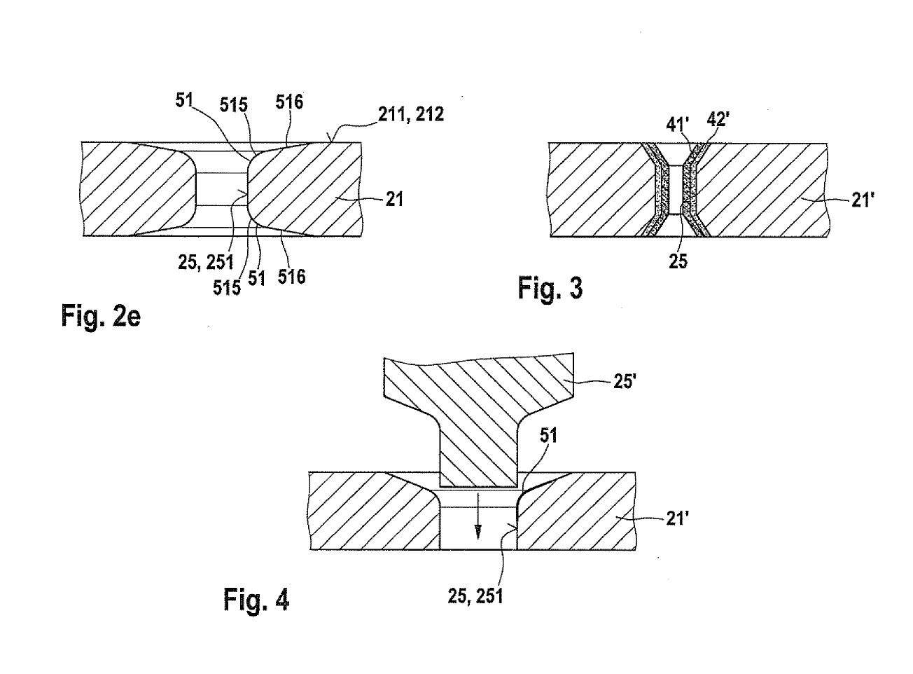

The production of a sensor element 20, particularly of a through-hole plating 200 of such a sensor element 20 is shown schematically in FIG. 3 in exemplary fashion, and is able to take place by inserting a plated-through hole 25 into an unfired solid electrolyte foil 21′, made, for instance, of Y, Ca and/or ZrO₂ stabilized using Sc, by punching, stamping and/or two-sided drilling, particularly using laser radiation. After that, a single or multiple insertion of an insulating paste 42′ and/or an insulating suspension into plated-through hole 25 takes place by printing, screen printing, one or two-sided suction/pressing, spray-on deposition and/or dripping, while finally, and, in the case of multiple insertions, additionally also intermediately, drying takes place. After that, a single or multiple insertion of a conductive paste 41′ into plated-through hole 25 takes place, by suction of conductive paste 41′ through plated-through hole 25 and/or by printing conductive paste 41′ onto the surface of solid electrolyte foil 21′.

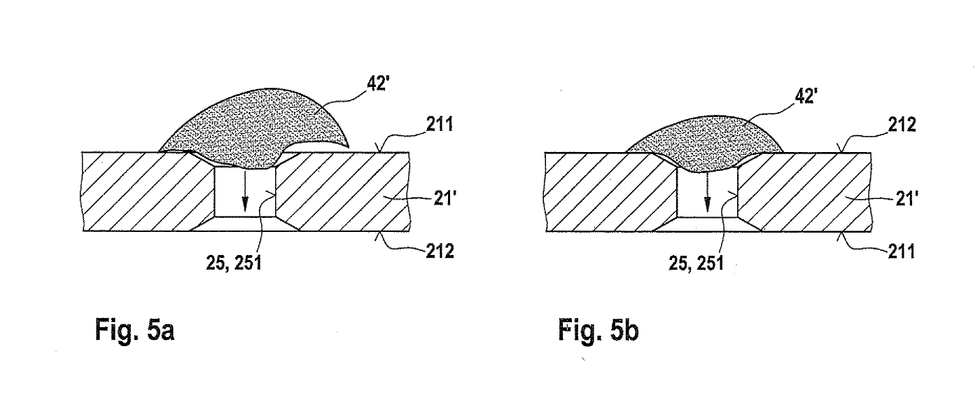

In one embodiment, for the production of a sensor element 20, especially for inserting a plated-through hole 25 into solid electrolyte foil 21′, a special tool 25′ is used which is developed as a mechanical drill or as a punching tool, see FIG. 4. The shape of the punching tool or the cutting surface developing in response to the rotation of the drill is cylindrical in the lower, distal subsection, and in the upwards adjacent proximal subsection of tool 25′ it corresponds to the shape of bevel 51 that is to be produced. Using this special tool 25′, it is also possible to produce just parts of plated-through hole 25, for instance, only the region having bevel 51, and to produce the remaining part of the bore in another manner. In this case, the lower, distal cylindrical part of tool 25′ would be omitted.

In another specific embodiment, additionally or alternatively to producing a sensor element 20 according to the present invention, especially for inserting an insulating paste 42′ and/or an insulating suspension into plated-through hole 25, first an insulating paste 42′ is applied onto upper side 211 of solid electrolyte foil 21′ in the area of plated-through hole 25, see FIG. 5a. It is provided that this insulating paste 42′ shall be sucked into the plated-through hole by applying an underpressure on lower side 212 of solid electrolyte foil 21′, so that a coating of wall 251 of the through-hole plating will take place.

It is further provided that the application and suction through should be repeated once or several times after turning over solid electrolyte foil 21′, insulating paste 42′ now being applied onto lower side 212 of solid electrolyte foil 21′, in the vicinity of plated-through hole 25, shown pointing upwards in FIG. 5b, and being suctioned through using underpressure in the direction of upper side 211 of solid electrolyte foil 21′, that now points downwards in FIG. 5b.

In one further preferred specific embodiment, it is provided in addition or alternatively that the underpressure, the consistency of insulating paste 42′ and the number of suctioning through operations and the shape of plated-through hole 25 shall be selected in such a way that, along the entire wall 251 of plated-through hole 25, a layer of insulating paste 42′ and/or of the insulating suspension is produced, whose thickness amounts to 5 μm to 35 μm, especially 10 μm to 25 μm.

In one further preferred specific embodiment, it is provided, additionally or alternatively, that to produce a sensor element 20, especially a through-hole plating 200 of such a sensor element 20, sintering, particularly at 1350° C. to 1450° C., be provided. In order to ensure that conducting element 41 and the insulating element are present as a co-sintered composite in the connected form, one of the following measures is applied, in this instance, a combination of the following measures is used or all the following measures are used:

Insulating paste 42′ and/or insulating suspension has particles of an insulating material, particularly aluminum oxide, and additional organic components, particularly softeners, solvents and binders, and conductive paste 41′ has particles of a noble metal, particularly platinum, and has particles of a solid electrolyte, particularly YSZ and additional organic components, particularly softeners, solvents and binders.

The size (d₉₀) of the particles of the insulating material, the size (d₉₀) of the particles of the noble metal and the size (d₉₀) of the particles of the solid electrolyte are all in the range of 0.8 μm to 2.5 μm.

The size (d₉₀) of the particles of the insulating material, the size (d₉₀) of the particles of the noble metal and the size (d₉₀) of the particles of the solid electrolyte differ by less than 50% of the largest of the three values.

The solid content (wt.-%) in insulating paste 42′ and/or in the insulating suspension differs from the solid content (wt.-%) in conductive paste 41′ by less than 20 wt.-%.

The content (wt.-%) of organic components differs in insulating paste 42′ and/or in the insulating suspension from the content (wt.-%) of organic components in conductive paste 41′ by less than 20 wt.-%.

Insulating paste 42′ and/or the insulating suspension and conductive paste 41′ contain the same organic components.

1-19. (canceled)

20. A sensor element for identifying a concentration of a gas component or a temperature of an exhaust gas of an internal combustion engine, the sensor element comprising:
a first solid electrolyte layer having a plated-through hole; and
a conducting element which produces an electrically conducting connection from an upper side of the first solid electrolyte layer to a lower side of the first solid electrolyte layer through the plated-through hole, the first solid electrolyte layer in the plated-through hole being electrically insulated from the conducting element by an insulating element;
wherein a wall of the plated-through hole has a bevel.

21. The sensor element as recited in claim 20, wherein the bevel reaches into the plated-through hole to a depth of not less than 25 μm.

22. The sensor element as recited in claim 21, wherein the depth is not less than 75 μm.

23. The sensor element as recited in claim 20, wherein the bevel reaches into the plated-through hole to a depth of not less than 5% of a thickness of the first solid electrolyte layer.

24. The sensor element as recited in claim 23, wherein the depth is not less than 15% of the thickness of the first solid electrolyte layer.

25. The sensor element as recited in claim 20, wherein the bevel has at least one straight region which is straight in a radial direction, the straight region of the bevel extending over the entire bevel.

26. The sensor element as recited in claim 25, wherein the straight region of the bevel includes an angle of not less than 15° and of not more than 75°, with at least one of the upper side of the first solid electrolyte layer and the lower side of the first solid electrolyte layer.

27. The sensor element as recited in claim 20, wherein the bevel has at least one curved region which is rounded off in a radial direction, a radius of curvature being 10 μm to 200 μm, the curved region of the bevel extending over the entire bevel.

28. The sensor element as recited in claim 20, wherein the bevel has a first partial bevel and a second partial bevel, the second partial bevel being situated between a large area of the solid electrolyte layer and the first partial bevel, the second partial bevel having an inclination of a wall in a radial direction lying between an inclination of the wall in the radial direction in the first partial bevel and an inclination of the large area of the solid electrolyte layer.

29. The sensor element as recited in claim 28, wherein the second partial bevel reaches into the plated-through hole to a depth of not less than 10 μm.

30. The sensor element as recited in claim 29, wherein the depth is not less than 30 μm.

31. The sensor element as recited in claim 28, wherein the second partial bevel reaches into the plated-through hole to a depth of not less than 2.5% of the thickness of the first solid electrolyte layer.

32. The sensor element as recited in claim 28, wherein the second partial bevel reaches into the plated-through hole to a depth of not less than 7.5% of a thickness of the first solid electrolyte layer.

33. The sensor element as recited in claim 28, wherein the second partial bevel reaches into the plated-through hole to a depth of not more than 100 μm.

34. The sensor element as recited in claim 28, wherein the second partial bevel reaches into the plated-through hole to a depth of not more than 50 μm.

35. The sensor element as recited in claim 28, wherein the second partial bevel reaches into the plated-through hole to a depth of not more than 20% of thickness of the first solid electrolyte layer.

36. The sensor element as recited in claim 34, wherein the second partial bevel reaches into the plated-through hole to a depth of not more than 10% of thickness of the first solid electrolyte layer.

37. The sensor element as recited in claim 28, wherein the first partial bevel and the second partial bevel are each straight at least in places in the radial direction, and abut on each other in the radial direction at a partial bevel angle of not less than 10° and of not more than 55°.

38. The sensor element as recited in claim 28, wherein the first partial bevel and the second partial bevel are each straight at least in places in the radial direction, and abut on each other in the radial direction at a partial bevel angle of not less than 25° and of not more than 45°.

39. The sensor element as recited in claim 28, wherein the second partial bevel includes an angle of not less than 3° and of not more than 25°, with at least one of the upper side of the first solid electrolyte layer and the lower side of the first solid electrolyte layer.

40. The sensor element as recited in claim 28, wherein the second partial bevel includes an angle of not less than 6° and of not more than 16°, with at least one of the upper side of the first solid electrolyte layer and the lower side of the first solid electrolyte layer.

41. The sensor element as recited in claim 28, wherein the second partial bevel is straight in the radial direction, at least in places, and the first partial bevel is rounded off in the radial direction, at least in places with a radius of curvature of 10 μm to 200 μm, and the second partial bevel and the first partial bevel abutting on each other in the radial direction at a partial bevel angle of less than 5°.

42. The sensor element as recited in claim 28, wherein the second partial bevel is straight in the radial direction, at least in places, and the first partial bevel is rounded off in the radial direction, at least in places with a radius of curvature of 25 μm to 115 μm, and the second partial bevel and the first partial bevel abutting on each other in the radial direction at a partial bevel angle of less than 1°.

43. The sensor element as recited in claim 28, wherein the wall of the plated-through hole has a bevel each on a lower edge and an upper edge of the plated-through hole.

44. The sensor element as recited in claim 28, wherein the insulating element is in the form of a layer on the wall of the plated-through hole and has a layer thickness along at least 90% of the wall of the plated-through hole, which is between a minimum layer thickness and a maximum admissible thickness, the minimum thickness being in a range between 5 μm and 14 μm and the maximum admissible thickness being in a range between 16 μm and 30 μm.

45. The sensor element as recited in claim 28, wherein the insulating element is in the form of a layer on the wall of the plated-through hole and has a layer thickness along at least 97% of the wall of the plated-through hole, which is between a minimum layer thickness and a maximum admissible thickness, the minimum thickness being in a range between 5 μm and 14 μm and the maximum admissible thickness being in a range between 16 μm and 30 μm.

46. The sensor element as recited in claim 28, wherein the insulating element has at least one of Al₂O₃ and a glass phase.

47. A method for producing a sensor element comprising:
producing an unburned solid electrolyte foil made of at least one of Y, Ca, and ZrO₂ stabilized with Sc;
inserting a plated-through hole into the solid electrolyte foil by one of punching, stamping or one-sided drilling, or two-sided drilling;
inserting at least one of an insulating paste and an insulating suspension into the plated-through hole by at least one of printing, screen printing, one-sided suction/pressing, two-sided suction/pressing, spray-on deposition, and dripping;
inserting a conductive paste into the plated-through hole at least one of by suctioning the conductive paste through the plated-through hole and by printing the conductive paste onto a surface of the solid electrolyte foil; and
sintering the sensor element, at least one of co-sintering of the conductive paste and the insulating paste taking place, co-sintering of the conductive paste and the insulating suspension taking place, co-sintering of the solid electrolyte foil and the insulating paste taking place, and co-sintering of the solid electrolyte foil and the insulating suspension taking place.

48. The method as recited in claim 47, wherein the insertion of the plated-through hole takes place using at least one of a mechanical drill, and a punching tool, at least one of the tools having a shape which one of corresponds to a shape of the plated-through hole that is to be inserted, or corresponds generally to a shape of at least a subsection of the plated-through hole that is to be inserted.

49. The method as recited in claim 47, wherein at least one of the insertion of an insulating paste and the insertion of the insulating suspension takes place by two-sided suction and includes:
applying the at least one of the insulating paste and the insulating suspension onto the upper side of the solid electrolyte foil in a vicinity of the plated-through hole;
sucking the at least one of the insulating paste and the insulating suspension through the plated-through hole by generating an underpressure on the lower side of the solid electrolyte foil in the vicinity of the plated-through hole;
applying the at least one of the insulating paste and the insulating suspension onto the lower side of the solid electrolyte foil in the vicinity of the plated-through hole; and
sucking the at least one of the insulating paste and the insulating suspension through the plated-through hole by generating an underpressure on the upper side of the solid electrolyte foil in the vicinity of the plated-through hole.

50. The method as recited in claim 49, wherein at least one of the underpressure, the consistency of the at least one of the insulating paste and the insulating suspension, a number and directions of the suctioning through, and a shape of the plated-through hole are selected in such a way that along an entire wall of the plated-through hole, a layer of the at least one of the insulating paste and the insulating suspension is produced, whose thickness amounts to 5 μm to 35 μm.

51. The method as recited in claim 49, wherein at least one of the underpressure, the consistency of the at least one of the insulating paste and the insulating suspension, a number and directions of the suctioning through, and a shape of the plated-through hole are selected in such a way that along an entire wall of the plated-through hole, a layer of the at least one of the insulating paste and the insulating suspension is produced, whose thickness amounts to 10 μm to 25 μm.

52. The method as recited in claim 47, wherein the at least one of the insulating paste and the insulating suspension includes particles of an insulating material, including aluminum oxide, and additional organic components, and the conductive paste includes particles of a noble metal, including platinum, and particles of a solid electrolyte, including YSZ and additional organic components, where at least one of the following conditions is satisfied:
a size of the particles of the insulating material, a size of the particles of the noble metal, and a size of the particles of the solid electrolyte are all in the range of 0.8 μm to 2.5 μm;
the size of the particles of the insulating material, the size of the particles of the noble metal and the size of the particles of the solid electrolyte differ by less than 50% of the largest of the three values;
solid content in the at least one of the insulating paste and the insulating suspension differs from solid content in the conductive paste by less than 20 wt.-%;
content of the organic components differs in the at least one of insulating paste and the insulating suspension from content of the organic components in the conductive paste by less than 20 wt.-%;
the at least one of the insulating paste and the insulating suspension and the conductive paste contain the same organic components.

53. The method as recited in claim 52, wherein all the conditions are satisfied.
